(19) United States
(12) Patent Application Publication
(10) Pub. No.: US 2016/0172571 A1
(43) Pub. Date: Jun. 16, 2016

(54) ELECTRICITY GENERATION UNIT FOR CONVERTING HEAT INTO ELECTRICAL ENERGY

(71) Applicant: GENTHERM GMBH, Odelzhausen (DE)

(72) Inventors: Dumitru-Cristian Leu, Freising (DE); Shaun Peter McBride, Augsburg (DE); Martin Adldinger, Holzheim (DE); Marco Ranalli, Augsburg (DE)

(21) Appl. No.: 14/903,570

(22) PCT Filed: Aug. 8, 2014
(86) PCT No.: PCT/DE2014/000404

§ 371 Date: Jan. 7, 2016

(30) Foreign Application Priority Data
Aug. 12, 2013 (DE) 10 2013 013 297.5

(51) Int. Cl. H01L 35/32

(52) U.S. Cl. CPC H01L 35/32

(57) ABSTRACT

The present invention relates to an electricity generation unit (100) equipped with:—at least one heat withdrawal chamber (23) for at least temporarily arranging a heat source (3) at least partially therein,—at least one shell (13) for delimiting the heat withdrawal chamber (23) from the surrounding environment thereof,—at least one thermoelectric converter (1) for converting heat into electrical energy. Provision is made for the thermoelectric converter (1) to be removable from the electricity generation unit (100), while the sleeve (13) of the working chamber can remain closed, unchanged.

### BACKGROUND OF THE INVENTION

The subject matter of the invention is an electricity generation unit for converting heat into electrical energy, according to the preamble of claim 1.

### PRIOR ART

In some technical applications, a need exists to convert heat into electricity, for example to allow the process waste heat from internal combustion engines, foundries or rolling mills to be utilized. This can be achieved using thermoelectric generators (TEG), which contain thermoelectric converters.

Thermoelectric generators of this type can be located, e.g. within a channel through which hot chemicals or heat-radiating products are transported, e.g. red-hot bottles, steel bars or other products that are manufactured or processed by casting processes or other thermal processes.

This involves a number of disadvantages. These include:
limited efficiency
varying localized temperature distributions to thermoelectric generators due to the varying distances from a heat source
soiling and corrosion on heat exchanging surfaces
diminishing efficiency with prolonged operation due to accumulated soiling
potential for localized thermal overloading
seals of water and power connections are located close to a hot heat source
costly maintenance due to poor accessibility of the thermoelectric generators while a device that generates waste heat is in operation

Thus a need for an improved utilization of waste heat exists.

### SUBJECT MATTER OF THE INVENTION

In light of this background, a technical concept having the features of claim 1 is proposed. Additional advantageous embodiments are found in the remaining claims and in the following description.

### FIGURES

Details of the invention are specified in the following description and in the claims. These specifications are intended to clarify the invention. However, they are merely exemplary in nature. Of course, one or more of the described features may also be omitted, modified or enhanced within the scope of the invention as defined by the independent claims. The features of different embodiments may of course also be combined with one another.

What is critical is that the concept of the invention must essentially be realized. When a feature is to be at least partially fulfilled, this includes cases in which said feature is also fully or substantially fully fulfilled. “Substantially” in this context means particularly that implementation allows the desired use to be achieved to a recognizable extent. This can mean, in particular, that a corresponding feature is at least 50%, 90%, 95% or 99% fulfilled. If a minimum quantity is indicated, more than said minimum quantity may, of course, also be used. When the number of a component is indicated as at least one, this also includes particularly embodiments having two, three or some other multiple of components. The same generally also applies when the indefinite article “a, an” is used. “A single” will be explicitly specified as such where necessary.

A description in reference to an object may also be applied to the majority or the entirety of all other objects of the same type. Unless otherwise indicated, intervals include their end points.

In the following, reference will be made to:

FIG. 1A a schematic longitudinal section of a steel rolling mill with two embodiments of an electricity generation unit 100 and 100′

FIG. 1B an enlarged view of detail a) of FIG. 1A

FIG. 1C an additional embodiment of an electricity generation unit 100″

### DESCRIPTION OF THE INVENTION

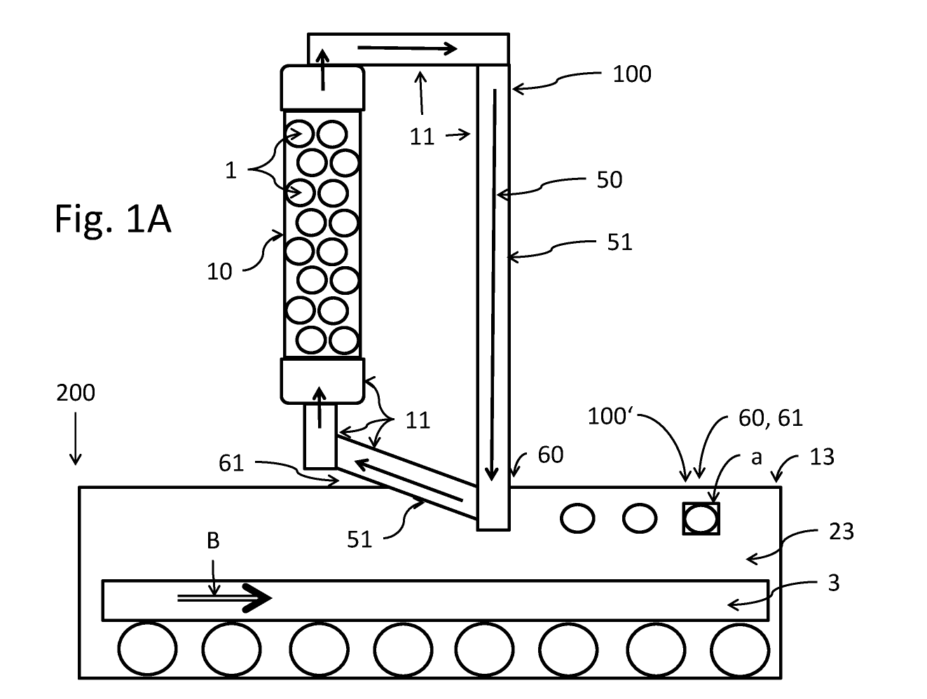

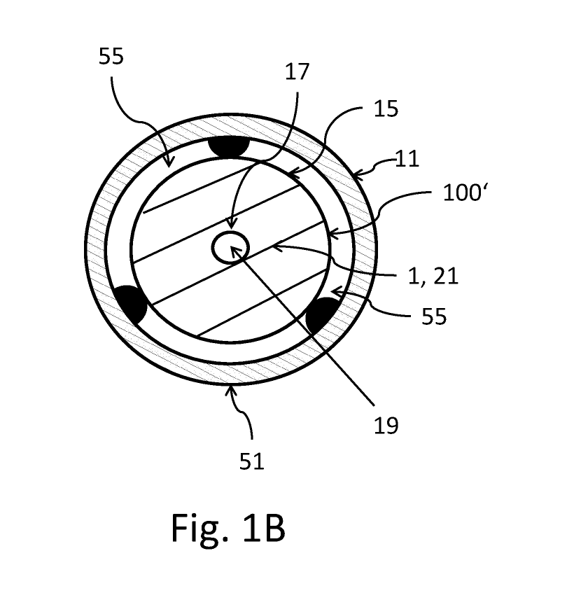

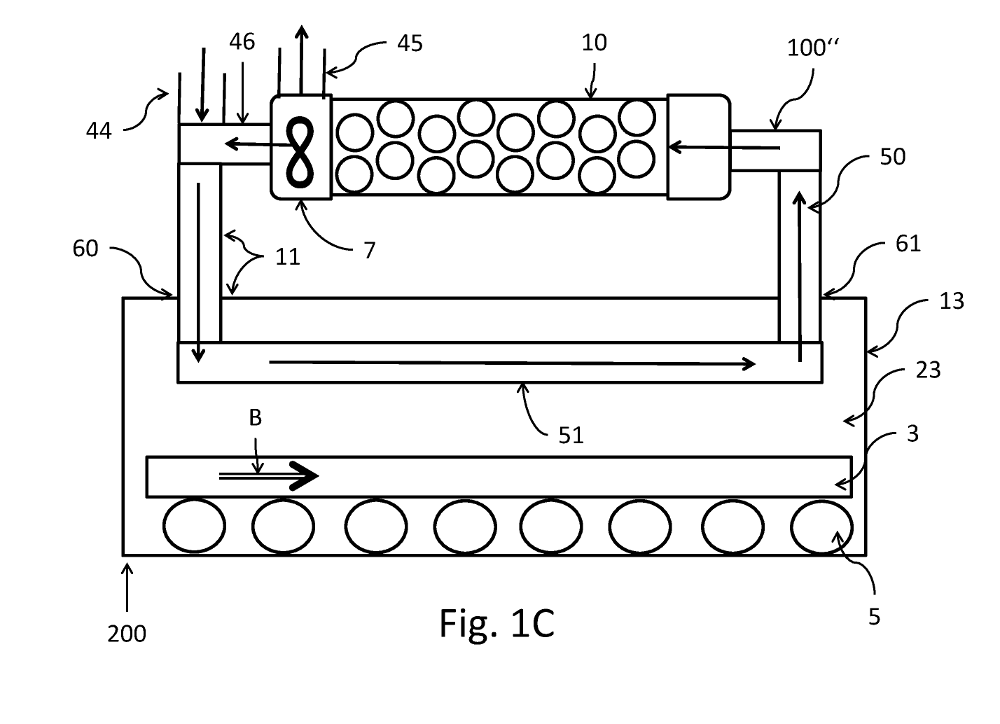

FIGS. 1A and 1C show a waste heat generation unit 200. This may be a motor, for example, or as in this case, a rolling mill for producing or processing metal bars.

Waste heat generation unit 200 has a heat source 3 or generates said heat source continuously. Heat source 3 is preferably a mass flow of gaseous, liquid and/or solid material, in this case red-hot, solid metal. Frequently this this is a mass flow which carries in it residual process heat that will be converted to electricity. Said mass flow may be a fluid flow, e.g. of heated water or hot waste gases from an internal combustion engine, or as in this case, a mass flow of a solid material. In the embodiment example, heat source 3 is red-hot rolled steel in or downstream of a rolling mill.

A transport device 5 is preferably provided for transporting at least one heat-carrying mass flow. In the present case, said device comprises rollers of a rolling mill, which transport steel bars through or out of the rolling mill. In the case of fluidic heat-carrying mass flows however, pumps, impeller wheels or other flow machines may also be provided as the transport device.

According to the invention, at least one electricity generation unit 100 is preferably provided for converting heat from heat source 3 into electrical energy. Said unit is preferably a thermoelectric generator or a device having at least one thermeoectric converter 1.

Waste heat generation unit 200, heat source 3 and/or electricity generation unit 100 are preferably equipped with at least one heat withdrawal chamber 23, or are at least partially arranged therein. Said chamber is understood to include a chamber region which is heated by a heat source 3 and in which electricity generation unit 100 directly or indirectly withdraws the thermal energy it requires from heat source 3. Heat withdrawal chamber 23 can also encompass a plurality of chamber regions that are structurally delimited from one another.

Preferably, at least one heat withdrawal chamber 23 is at least partially encompassed by a shell 13. Shell 13 can be formed at least partially by a waste gas pipe of an engine, for example, or as in this case by a housing of a rolling mill or of the component parts thereof. Shell 13 serves particularly to shield heat source 3 from the area surrounding it. This serves to protect the surrounding area against the effects of excessive heat. At the same time, the shell prevents any loss of thermal energy. Shell 13 can be embodied as a device for conducting the heat-carrying mass flow, e.g. as pipes through which hot waste water flows. However, it may also be arranged, as in this embodiment example, spaced from the heat-carrying mass flow of heat source 3. This is expedient particularly in the case of high-temperature heat sources 3, as it protects shell 13 against excessive thermal loads. In some cases it is expedient for shell 13 to be hermetically sealed, however in cases such as the present case this is not mandatory.

Heat withdrawal chamber 23 and/or shell 13 thereof can be components of electricity generation unit 100. Heat withdrawal chamber 23 can also be a separate component between electricity generation unit 100 and waste heat generation unit 200. In the present case, heat withdrawal chamber 23 is embodied as a component of waste heat generation unit 200.

An electricity generation unit 100 has at least one thermoelectric converter 1 for converting heat directly into electricity. This is understood, for example, as a component that is capable of converting heat directly into electrical voltage. In this case, this is preferably a plurality of Seebeck elements electrically connected in series.

At least one thermoelectric converter 1 preferably has one or more thermoelectric elements 21. These are understood particularly as Peltier and Seebeck elements. Preferably, one or more of such thermoelectric elements 21 are embodied as flat, annular disks. These are preferably stacked one on top of the other so as to multiply the amount of electrical voltage that can be tapped. This preferably results in a thermoelectric converter 1 in the form of a tubular structure having a cylindrical exterior at an outer diameter and a cylindrical interior at an inner diameter.

At least one thermoelectric element 21 preferably has a warm side 15. In the case of the annular disks, this corresponds to the outer side at the outer diameter of a thermoelectric element 21. This is where the exchange of heat between heat source 3 and thermoelectric converter 1 or one or more thermoelectric elements 21 takes place.

At least one thermoelectric element 21 preferably has at least one cold side 17. In the case of the annular disks, cold side 17 corresponds to the inner side at the inner diameter of a thermoelectric element 21.

Cold side 17 is preferably cooled by a cooling fluid 19, which flows through the hollow inner diameter of thermoelectric elements 21, that is, through the annular disks. In this manner, the temperature on cold side 17 is preferably kept constant. Cooling fluid 19 is preferably circulated in a cooling fluid circuit or is provided via a continuously supplied cooling fluid flow. In the interest of clarity however, this is not illustrated here in detail.

An electricity generation unit 100, a waste heat generation unit 200 and/or a heat withdrawal chamber 23 have at least one heat withdrawal channel 11. Said channel penetrates at least partially into heat withdrawal chamber 23 at least at one passage opening. At least sections of said channel preferably extend linearly. Said section is preferably spaced from shell 13 and/or aligned at an angle relative thereto.

At least sections of heat withdrawal channel 11 are preferably tubular in shape. Such a tube can be circular, oval or even rectangular in cross-section. Heat withdrawal channel 11 preferably enters heat withdrawal chamber 23 in such a way that fluid or hot material cannot exit heat withdrawal chamber 23 at the common boundary region. This can be ensured, for example, by welding heat withdrawal channel 11 to heat withdrawal chamber 23 along their common boundaries.

Heat withdrawal channel 11 preferably has a wall 51. Said wall is preferably made of a thermally resistant material. This can be pipes made of stainless steel or titanium, for example. The material is preferably highly thermally conductive. For high temperature applications, however, lower thermal conductivity may be preferable. Wall 51 is provided for preventing direct contact between the hot material in the heat withdrawal chamber and a heat withdrawal fluid 50 located in heat withdrawal channel 11 and/or a thermoelectric converter 1. It also serves as a fluid conducting device when a heat withdrawal fluid 50 is flowing through heat withdrawal channel 11.

Heat withdrawal channel 11 preferably penetrates heat withdrawal chamber 23 in such a way that at least one entry point 60 and at least one exit point 61 are created. A thermoelectric converter 1 arranged between these two positions is thereby accessible from two sides. A heat withdrawal fluid 50 flowing through heat withdrawal channel 11 can thus enter at entry point 60 and can be withdrawn from heat withdrawal chamber 23 at exit point 61.

If a thermoelectric converter 1 inside a heat withdrawal channel 11 is located within heat withdrawal chamber 23, at least one end of heat withdrawal channel 11 preferably essentially does not project beyond shell 13 of heat withdrawal chamber 23. This improves the accessibility of thermoelectric converter 1 located inside heat withdrawal channel 11.

If one or more thermoelectric converters 1 inside a heat withdrawal channel 11 are located within heat withdrawal chamber 23, they preferably take up at least 50% of the distance between entry point 60 and exit point 61, preferably at least 80%, preferably substantially entirely.

If one or more thermoelectric converters 1 inside a heat withdrawal channel 11 are located within heat withdrawal chamber 23, they preferably take up at least 30% of the area of the open cross-section of heat withdrawal channel 11, preferably at least 50%, preferably no more than 95%.

When a thermoelectric converter 1 is located within a heat withdrawal chamber 23, this does not mean that it comes into direct contact with the medium or the heat source 3 located there. Rather, it means that said converter is located within the shell 13 of heat withdrawal chamber 23, which is embodied as closed. Said converter always remains separated from heat withdrawal chamber 23 by wall 51 of heat withdrawal channel 11.

In this connection, it can be expedient to provide spacers 12, which keep a thermoelectric converter 1 that is arranged inside heat withdrawal channel 11 spaced from wall 51 of heat channel 11. Said spacers can be strip-type fixed members arranged along thermoelectric converter 1 or along heat withdrawal channel 11. They may also be nubs that keep thermoelectric converters 11 spaced in relation to wall 51 at points. It is further conceivable for at least one spacer 12 to be embodied as a film, ring or pipe which keeps thermoelectric converter 1 spaced from heat withdrawal channel 11. Spacers 12 can be embodied as a film-type insulating material, e.g. glass wool or a silicon coating, but may also be made of the material of wall 51. In the present example, said spacer is a fixed member made of metal and arranged along the tubular heat withdrawal channel 23. In the present case, this is a weld seam in the form of a bead.

This results in one or more intermediate spaces 55 formed between wall 51 and at least one thermoelectric converter 1. Said spaces facilitate the removal of the thermoelectric converter from heat withdrawal channel 11. This is important since the dimensions of the two components can change substantially as a result of extreme temperature fluctuations, and therefore the thermoelectric converter could otherwise become stuck in heat withdrawal channel 11. Furthermore, an intermediate space 55 that is filled with air or with an insulating material protects thermoelectric converter 1 from becoming overloaded by extremely high temperatures.

An entry point 60 and an exit point 60 can be located opposite one another at the same height relative to a direction of movement B of heat source 3, as in electricity generation unit 100′.

However the distance between entry point 60 and an exit point 60 can also have at least one directional component along direction of movement B, so that entry point and exit point are located at different heights from one another relative to a direction of movement B of heat source 3, as in electricity generation units 100 and 100″.

When a heat withdrawal fluid 50 is flowing through heat withdrawal channel 11, it can be expedient in most cases to alternatively or additionally arrange thermoelectric converter 1 outside of heat withdrawal chamber 23, in order to optimize utilization of the available flow cross-section within heat withdrawal channel 11.

When a thermoelectric converter 1 is arranged inside heat withdrawal channel 11 but outside of heat withdrawal chamber 23, at least one of the two ends of heat withdrawal channel 11 preferably extends beyond shell 13 of heat withdrawal chamber 23, in order to further convey a heat withdrawal fluid 50.

When a thermoelectric converter 1 is arranged inside heat withdrawal channel 11 but outside of heat withdrawal chamber 23, preferably at least one, but more preferably a plurality of thermoelectric converters 1 are arranged in a converter module 10. The cross-section of this converter module 10 is preferably enlarged in relation to the cross-section of the remaining heat withdrawal channel 11. This allows compensation for the cross-section that is blocked by thermoelectric converter 1, so that the flow rate remains constant. It can also be provided that the cross-sectional area of the available inner open flow cross-section in converter module 10 is greater than the open flow cross-section in the remainder of heat withdrawal channel 11. As a result, the flow rate of heat withdrawal fluid 50 within converter module 10 is reduced. This is advantageous for a heat exchange between heat withdrawal fluid 50 and thermoelectric converters 1.

In some cases, converter module 10 is a container having a plurality of pipes which are open to the exterior but which do not allow the contents of the container to pass to the exterior, as in the case of electricity generation units 100 and 100″. Rod-like thermoelectric modules are then introduced into the pipes. Said modules can also be removed from the pipes without opening the container. This is important particularly in systems that involve radioactive, aggressive or hot media.

Heat withdrawal channel 11 preferably has at least one fluid infeed device 44. Said device may simply be one end of a pipeline. However, it may also be a valve or a more complex type of fluid supply device.

Heat withdrawal channel 11 preferably has at least one fluid withdrawal device 45. It can have the same configuration as fluid infeed device 44.

In embodiments or operating states in which a fluid return device is not provided or is not in operation, and heat channel 11 is thus an open system, the desired volumetric flow rate for a heat withdrawal fluid 50 can preferably be adjusted by adjusting the degree of opening of fluid infeed device 44 and/or fluid withdrawal device 45.

Preferably however, heat withdrawal channel 11 has at least one fluid return device 46. Said device is expediently a channel section that connects the beginning and end of heat withdrawal channel 11 to form a closed loop. However, it may also be a throttle valve or the like, particularly when combined with the fluid infeed or withdrawal device.

A heat withdrawal fluid 50 may be transported within heat withdrawal channel 11 by means of natural convection, since a localized temperature increase in a heat withdrawal fluid 50 by means of heat source 3 will result in a tendency of heat withdrawal fluid 50 to rise. This is particularly effective for embodiments in which at least sections of a heat withdrawal channel 11 are arranged along and/or parallel to the alignment and/or direction of movement B of a heat source 3 in heat withdrawal chamber 23.

For some applications, it may be expedient to feed a heat withdrawal fluid 50 into heat withdrawal channel 11 via a fluid infeed device 44. In some cases, once the heat withdrawal fluid has flowed through heat withdrawal chamber 23 and following a heat exchange with a thermoelectric converter 1, it may be expedient to withdraw said fluid from heat withdrawal channel 11 via a fluid withdrawal device 45. This flow movement can be implemented without additional drive means, solely by means of the natural tendency of hot media to rise.

For certain applications it may be expedient to arrange a fluid pumping device 7 in heat withdrawal channel 11, at fluid infeed device 44 and/or at fluid withdrawal device 45. Such a fluid pumping device 7 allows the volume of heat withdrawal fluid 50 that is pumped to be influenced. An overheating of wall 51 of heat withdrawal channel 11 within the heat withdrawal chamber and/or an overheating of thermoelectric converter 1, for example, can thereby be prevented. When the thermal load on heat withdrawal fluid 50 is lower, the flow rate can be correspondingly reduced in order to increase the transfer of heat between heat withdrawal chamber 23 and heat withdrawal fluid 50 and/or between heat withdrawal fluid 50 and thermoelectric converter 1.

Furthermore, when a fluid pumping device 7 is used, fluid can flow through heat withdrawal channel 11 in two different directions.

Particularly in cases in which shell 13 is exposed to high thermal loads, this can be advantageous for operating the section of heat withdrawal channel 11 that is located within heat withdrawal chamber 23 in the manner of a direct-current heat exchanger. This is understood to mean that heat withdrawal fluid 50 flows in the same direction in which a heat source 3 is moving within heat withdrawal chamber 23. The hottest point in heat withdrawal channel 11 is thereby cooled by the coolest possible heat withdrawal fluid 50.

If the temperature of heat source 3 is significantly lower than the melting point, which is the most favourable operating point for thermoelectric converter 1, this lends itself to operation in the manner of a countercurrent heat exchanger. This means that the direction of flow of heat withdrawal fluid 50 is directed at least in sections substantially opposite the direction of movement of heat source 3 within heat withdrawal chamber 23. This includes movements in which, in a vector analysis, the directional fraction opposite the direction of movement of heat source 3 is at least as great as its directional fraction perpendicular to said direction of movement.

The flow direction of fluid pumping device 7 is preferably reversible, particularly if the temperature of the available heat source fluctuates substantially.

For some applications, to achieve better accessibility it can be expedient to arrange a heat withdrawal channel 11 and/or the thermoelectric converters 1 arranged therein vertically. The thermoelectric converters 1 can then be removed using a crane, for example. In the case of electricity generation unit 100′ shown in FIG. 1, however, a horizontal arrangement is preferred, in order to achieve a uniform thermal load of thermoelectric converters 1 over their entire length.

When a thermoelectric converter 1 is located outside of a heat withdrawal chamber 23, and if a heat source 3 has a direction of movement or flow within heat withdrawal chamber 23, at least sections of least one heat withdrawal channel 11 are preferably arranged along this direction of movement B. This includes pathways that are angled in relation to said direction of movement, particularly if the angle in relation to the direction of movement is smaller than 45°.

When at least sections of a heat withdrawal channel 11 are arranged along a direction of movement of a heat source 3, it is expedient, particularly with embodiments that utilize natural convection for transporting heat withdrawal fluid 50, for the distance between the heat withdrawal channel and heat source 3 to decrease in the direction of movement of heat source 3, and/or for the height of heat withdrawal channel 11 to drop in this direction. Both permit the heated fluid to ascend toward the warmer withdrawal point. For applications in which the temperature of the withdrawan heat withdrawal fluid 50 would be undesirably high, the aforementioned angling of heat withdrawal channel 11 can also be reversed. The fluid withdrawal point is thereby moved to a cooler zone.

The invention thus enables thermoelectric elements and thermoelectric generators that are used, e.g., in the chemicals and metallurgical industries to be replaced without interrupting the main industrial process.

### Particularly Preferred Features

Particularly preferred is an electricity generation unit 100 for withdrawing heat from at least one heat withdrawal chamber 23 in which a heat source 3 is at least temporarily at least partially arranged, wherein heat withdrawal chamber 23 has at least one shell 13 for delimiting heat withdrawal chamber 23 from the area surrounding it, and electricity generation unit 100 is equipped with at least one thermoelectric converter 1 for converting heat into electrical energy. It is also expedient for thermoelectric converter 1 to be removable from electricity generation unit 100 while shell 13 of operating chamber 23 remains closed. This facilitates maintenance of the thermoelectric generators.

Particularly preferred is an electricity generation unit 100 in which at least one thermoelectric converter 1 is arranged inside a heat withdrawal channel 11, at least sections of which are in turn arranged within heat withdrawal chamber 23. This increases efficiency.

Particularly preferred is an electricity generation unit 100 in which heat withdrawal channel 11 penetrates heat withdrawal chamber 23 at least at one point and/or in which the main direction of extension of said channel intersects at least in sections with the shell of heat withdrawal chamber 23 and/or is aligned running up to the heat source. This results in a larger surface for heat exchange.

Particularly preferred is an electricity generation unit 100 in which at least one heat withdrawal channel 11 has at least one wall 51 which delimits the interior of heat withdrawal channel 11 at least partially in relation to heat withdrawal chamber 23, in which at least one thermoelectric converter 1 is arranged at least partially inside heat withdrawal channel 11 and at least partially within heat withdrawal chamber 23, in which thermoelectric converter 1 is arranged at least partially spaced from wall 51, and in which thermoelectric converter 1 is arranged concentrically and/or parallel in relation to wall 51. A uniform temperature application and easy removal are thereby achieved.

Particularly preferred is an electricity generation unit 100 in which at least one thermoelectric converter 1 or at least one wall 51 of a heat withdrawal channel 11 are held spaced from one another by means of one or more spacers 12. This facilitates withdrawal even in the case of temperature and size fluctuations.

Particularly preferred is an electricity generation unit 100 in which at least one spacer 12 is mounted on thermoelectric converter 1, on wall 51 or separately from both. Depending on the intended use, one of these options is particularly easy to install.

Particularly preferred is an electricity generation unit 100 in which an intermediate space 55 is provided between a thermoelectric converter 1 and a wall 51 of a heat withdrawal chamber 23 to facilitate a removal of thermoelectric converter 1 from heat withdrawal chamber 23.

Particularly preferred is an electricity generation unit 100 in which at least one thermoelectric converter 1 is located outside of a heat withdrawal chamber 23 to allow thermoelectric converter 1 to be removed without intervention into heat withdrawal chamber 23, in which at least one heat withdrawal channel 11 is filled at least partially with a heat withdrawal fluid 50 and in which a transfer of heat from a heat source 3 to thermoelectric converter 1 is based on a flow of heat withdrawal fluid 50 along heat withdrawal channel 11. This increases efficiency.

Particularly preferred is an electricity generation unit 100 in which a plurality of thermoelectric converters 1 are arranged in a converter module 10 and in which converter module 10 is located outside of a heat withdrawal chamber 23. This facilitates maintenance and assembly.

1. An electricity generation unit for withdrawing heat from at least one heat withdrawal chamber, in which a heat source is at least temporarily at least partially arranged,
wherein the heat withdrawal chamber has at least one shell for delimiting the heat withdrawal chamber from the area surrounding the heat withdrawal chamber and the electricity generation unit is equipped with at least one thermoelectric converter for converting heat into electrical energy,
wherein the thermoelectric converter can be removed from the electricity generation unit while the shell of the operating chamber-remains closed.

2. The electricity generation unit according to claim 1, wherein at least one thermoelectric converter is arranged inside a heat withdrawal channel, at least sections of which are in turn arranged within the heat withdrawal chamber.

3. The electricity generation unit according to claim 2, wherein the heat withdrawal channel penetrates the heat withdrawal chamber at least at one point and/or the main direction of extension of said channel intersects at least in sections with the shell of the heat withdrawal chamber and/or is aligned running up to the heat source.

4. The electricity generation unit according to claim 3, wherein:
at least one heat withdrawal channel has at least one wall which delimits the interior of the heat withdrawal channel at least partially in relation to the heat withdrawal chamber,
in that at least one thermoelectric converter is arranged at least partially inside the heat withdrawal channel and at least partially within the heat withdrawal chamber,
in that the thermoelectric converter is arranged at least partially spaced from the wall,
and in that the thermoelectric converter is arranged concentrically and/or parallel in relation to the wall.

5. The electricity generation unit according to claim 1, wherein the at least one thermoelectric converter or at least one wall of a heat withdrawal channel are held spaced from one another by means of one or more spacers.

6. The electricity generation unit according to claim 1, wherein at least one spacer is mounted on the thermoelectric converter, on a wall, or separately from both.

7. The electricity generation unit according to claim 1, wherein an intermediate space is provided between a thermoelectric converter and a wall of a heat withdrawal chamber to facilitate a removal of the thermoelectric converter from the heat withdrawal chamber.

8. The electricity generation unit according to claim 1, wherein at least one thermoelectric converter is located outside of a heat withdrawal chamber to allow the thermoelectric converter to be removed without intervention into the heat withdrawal chamber, in that at least one heat withdrawal channel is filled at least partially with a heat withdrawal fluid and in that a transfer of heat from a heat source to the thermoelectric converter is based on a flow of the heat withdrawal fluid along the heat withdrawal channel.

9. The electricity generation unit according to claim 1, wherein a plurality of thermoelectric converters are arranged in a converter module and in that a converter module is located outside of a heat withdrawal chamber.

10. The electricity generation unit according to claim 2, wherein the at least one thermoelectric converter or at least one wall of the heat withdrawal channel are held spaced from one another by means of one or more spacers.

11. The electricity generation unit according to claim 4, wherein the at least one thermoelectric converter or at least one wall of the heat withdrawal channel are held spaced from one another by means of one or more spacers.

12. The electricity generation unit according to claim 2, wherein at least one spacer is mounted on the thermoelectric converter, on a wall, or separately from both.

13. The electricity generation unit according to claim 4, wherein at least one spacer is mounted on the thermoelectric converter, on a wall, or separately from both.

14. The electricity generation unit according to claim 11, wherein at least one spacer is mounted on the thermoelectric converter, on a wall, or separately from both.

15. The electricity generation unit according to claim 4, wherein an intermediate space is provided between the at least one thermoelectric converter and a wall of a heat withdrawal chamber to facilitate a removal of the thermoelectric converter from the heat withdrawal chamber.

16. The electricity generation unit according to claim 14, wherein an intermediate space is provided between the at least one thermoelectric converter and a wall of a heat withdrawal chamber to facilitate a removal of the thermoelectric converter from the heat withdrawal chamber.

17. The electricity generation unit according to claim 4, wherein at least one thermoelectric converter is located outside of a heat withdrawal chamber to allow the thermoelectric converter to be removed without intervention into the heat withdrawal chamber, in that at least one heat withdrawal channel is filled at least partially with a heat withdrawal fluid and in that a transfer of heat from a heat source to the thermoelectric converter is based on a flow of the heat withdrawal fluid along the heat withdrawal channel.

18. The electricity generation unit according to claim 16, wherein at least one thermoelectric converter is located outside of a heat withdrawal chamber to allow the thermoelectric converter to be removed without intervention into the heat withdrawal chamber, in that at least one heat withdrawal channel is filled at least partially with a heat withdrawal fluid and in that a transfer of heat from a heat source to the thermoelectric converter is based on a flow of the heat withdrawal fluid along the heat withdrawal channel.

19. The electricity generation unit according to claim 4, wherein a plurality of thermoelectric converters are arranged in a converter module and in that a converter module is located outside of a heat withdrawal chamber.

20. The electricity generation unit according to claim 18, wherein a plurality of thermoelectric converters are arranged in a converter module and in that a converter module is located outside of a heat withdrawal chamber.
